(19) United States
(12) Patent Application Publication
(10) Pub. No.: US 2025/0112122 A1
(43) Pub. Date: Apr. 3, 2025

(54) BACKSIDE POWER GATING

(71) Applicant: INTEL CORPORATION, SANTA CLARA, CA (US)

(72) Inventors: Kevin P. O'Brien, Portland, OR (US); Paul Gutwin, Williston, VT (US); David L. Kencke, Beaverton, OR (US); Mahmut Sami Kavrik, Eugene, OR (US); Daniel Chanemougame, Niskayuna, NY (US); Ashish Verma Penumatcha, Hillsboro, OR (US); Carl Hugo Naylor, Portland, OR (US); Kirby Maxey, Hillsboro, OR (US); Uygar E. Avci, Portland, OR (US); Tristan A. Tronic, Aloha, OR (US); Chelsey Dorow, Portland, OR (US); Andrey Vyatskikh, Hillsboro, OR (US); Rachel A. Steinhardt, Beaverton, OR (US); Chia-Ching Lin, Portland, OR (US); Chi-Yin Cheng, Hillsboro, OR (US); Yu-Jin Chen, Hillsboro, OR (US); Tyrone Wilson, Hillsboro, OR (US)

(73) Assignee: INTEL CORPORATION, SANTA CLARA, CA (US)

(21) Appl. No.: 18/477,906

(22) Filed: Sep. 29, 2023

(51) Int. Cl. H01L 23/48; H01L 23/528; H01L 27/092; H01L 29/06; H01L 29/18; H01L 29/423; H01L 29/78

(52) U.S. Cl. CPC H01L 23/481; H01L 23/5283; H10D 30/6211; H10D 30/6735; H10D 62/121; H10D 62/84; H10D 84/853

(57) ABSTRACT

Integrated circuit (IC) devices and systems with backside power gates, and methods of forming the same, are disclosed herein. In one embodiment, an integrated circuit die includes a device layer with one or more transistors, a first interconnect over the device layer, a second interconnect under the device layer, and one or more power gates under the device layer.

### BACKGROUND

Voltage regulation (VR) circuits take up significant silicon area on modern integrated circuit (IC) chips. For example, a VR circuit typically uses power gates to switch power on and off to various power-gated circuit blocks on a chip. These power gates are generally implemented using transistors, which means they take up valuable silicon area that could otherwise be used for logic circuitry.

### BRIEF DESCRIPTION OF THE DRAWINGS

FIG. 1 illustrates a block diagram of an example integrated circuit with backside power gates.

FIGS. 2A-C illustrate an example embodiment of horizontal backside power gates.

FIGS. 3A-C illustrate an example embodiment of vertical backside power gates.

FIG. 4 illustrates a cross-section of an example integrated circuit with backside power gates.

FIG. 5 illustrates a flowchart for forming an integrated circuit with backside power gates.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIGS. 8A-D are perspective views of example planar, FinFET, gate-all-around, and stacked gate-all-around transistors.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Voltage regulation (VR) circuits take up significant silicon area on modern integrated circuit (IC) chips, which consequentially increases costs. For example, a VR circuit typically uses power gates to switch power on and off to various power-gated circuit blocks on a chip. These power gates are generally implemented using transistors, which means they take up valuable silicon area that could otherwise be used for logic circuitry.

Accordingly, this disclosure presents embodiments of integrated circuits (ICs) with backside power gating, along with methods of forming the same. This solution moves power gates from the frontside silicon layer to backside layers using thin-film transistors (e.g., transistors formed with thin films such as two-dimensional (2D) semiconductor films, metal oxide films, etc.), which saves significant silicon area (e.g., up to 10% in some cases).

In some embodiments, for example, backside power gating may be implemented on chips with backside power delivery (BPD) architectures, which generally include a frontside interconnect for signaling and a backside interconnect for power delivery. In these architectures, thin-film transistors used for backside power gating may be formed between/within backside metal (BM) layers in the backside interconnect. In this manner, thin-film transistors formed in the backside power layers are used to replace traditional frontside silicon layer VR circuits, thus saving valuable silicon area that would otherwise be consumed by the frontside VR circuits. Further, moving the VR power gate transistors to the backside also enables other layout changes that provide additional performance gains, such as decreasing resistance and lowering power loss, which makes the voltage regulator more efficient. This solution provides various advantages, including reduced silicon area, lower cost, and better energy efficiency.

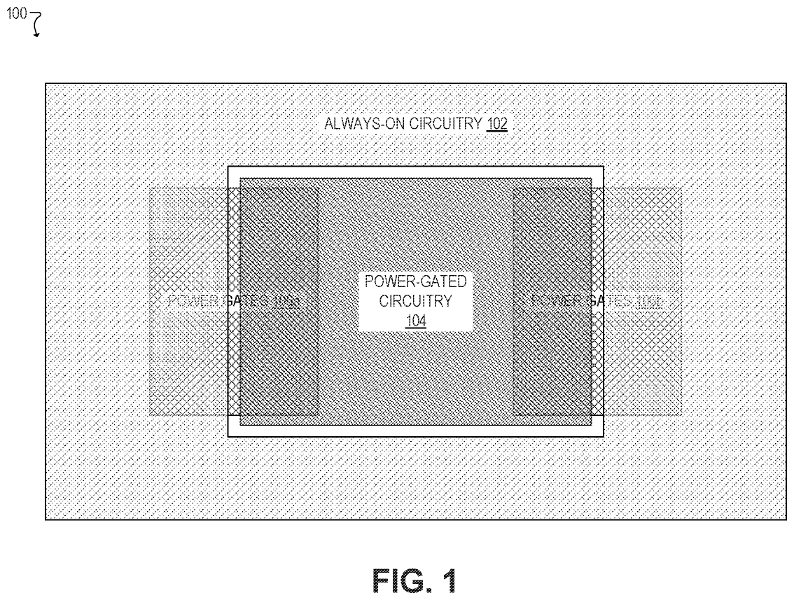

FIG. 1 illustrates a block diagram of an example integrated circuit (IC) 100 with backside power gating. In the illustrated embodiment, IC 100 includes always-on circuitry 102, power-gated circuitry 104, and backside power gates/switches 106a-b. The always-on circuitry 102 is always supplied with power when IC 100 is powered on, while the power-gated circuitry 104 is only supplied with power when in use. For example, when the power-gated circuitry 104 is in use, power from the always-on circuitry 102 is supplied to the power-gated circuitry 104 by the power gates 106a-b.

In some embodiments, for example, the always-on circuitry 102 and power-gated circuitry 104 may be organized into rows of circuits blocks, or cells. Moreover, each row may have power supply (V_{DD}) and ground (V_{SS}) rails to supply power to the respective circuit blocks 102, 104 in that row. Each row may also have one or more power gates 106a-b to switch the power supply (V_{DD}) and/or ground (V_{SS}) rails for the power-gated circuit blocks 104 in that row. In this manner, the always-on circuit blocks 102 are always powered, but the power-gated circuit blocks 104 are only powered when the power gates 106a-b for that row are activated. For example, when the power gates 106a-b for a given row are activated, power from the always-on circuit blocks 102 is supplied to the power-gated circuit blocks 104 through the power gates 106a-b. Typically all power-gated circuit rows 104 will, after some transition time, be in either the on or off state.

In some embodiments, for example, the power gates 106a-b may include transistors positioned between the always-on 102 and power-gated 104 circuit blocks, and the source and drain terminals of the transistors may be connected to the power supply (V_{DD}) and ground (V_{SS}) rails for those circuit blocks 102, 104. When voltage is applied to the transistor gate of a power gate 106a-b, current flows between the transistor source and drain terminals from the always-on circuit blocks 102 to the power-gated circuit blocks 104.

Further, in the illustrated embodiment, the power gates 106a-b are implemented on the backside of IC 100 using thin-film transistors (e.g., transistors formed with 2D semiconductor films, metal oxide films), which enables the footprint of the power gates 106a-b to overlap with the always-on 102 and power-gated 104 circuitry without taking away any silicon area from those circuit blocks. By comparison, frontside power gates are formed on the same silicon substrate as the always-on circuitry and the power-gated circuitry, which means they would be positioned between the always-on and power-gated circuitry without any overlap, thus taking away silicon area from those circuit blocks.

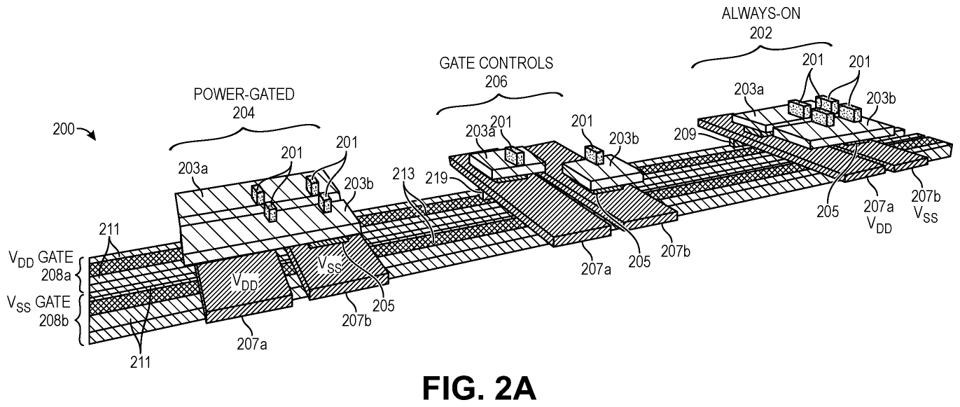

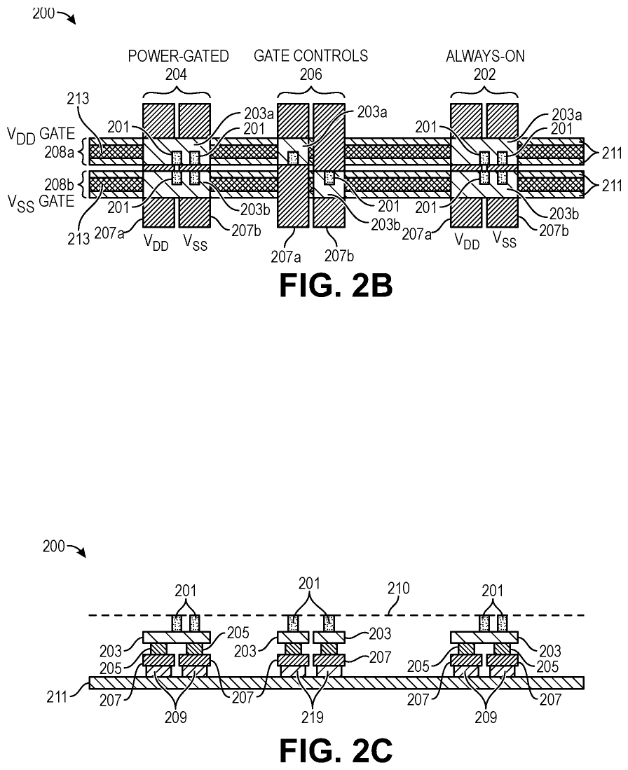

In some embodiments, the power gates 106a-b may be implemented using the embodiments shown and described below with respect to FIGS. 2, 3, and 4.

FIGS. 2A-C illustrate an example embodiment of horizontal backside power gates 200 for a single circuit row. In particular, perspective, plan, and cross-section views of the power gates 200 are shown in FIGS. 2A, 2B, and 2C, respectively. In the illustrated example, only the devices and interconnects on the backside of the die/chip are shown, while the devices and interconnects on the frontside (e.g., above the backside/frontside plane 210 shown in FIG. 2C) are omitted for simplicity. In the illustrated embodiment, power gates or transistors 208a-b for the power supply (V_{DD}) and ground (V_{SS}) rails extend horizontally between the power rails for the power-gated 204 and always-on 202 circuitry, with gate controls 206 in the middle. For frontside gating, these transistors are typically oriented with the conducting channel in the normal horizontal orientation parallel to the circuit row with a much narrower width due to silicon area constraints. By moving the gates/transistors 208a-b to the backside, the conducting channel can be rotated 90 degrees to be orthogonal to the circuit row and extended in width, which decreases resistance and lowers power loss, while also saving silicon area.

In the illustrated embodiment, the always-on and power-gated circuitry 202, 204 respectively include power supply (V_{DD}) and ground (V_{SS}) rails patterned in the first and second backside metal layers 203, 207 and connected by vias 201, 205. The gate controls 206 include control rails patterned in the first and second backside metal layers 203, 207 and connected by vias 201, 205, which are used to control the transistors 208a-b for the power supply (V_{DD}) and ground (V_{SS}) rails.

Further, one of the transistors 208a switches the power supply (V_{DD}) rail (referred to as the header switch) and the other transistor 208b switches the ground (V_{SS}) rail (referred to as the footer switch). For example, with respect to the V_{DD} transistor 208a, one of the source/drain contacts 209 is connected to the V_{DD} rail 207a of the always-on circuitry 202, and the other source/drain contact 209 is connected to the V_{DD} rail 207a of the power-gated circuitry 204. Further, the gate contact 219 is connected to the V_{DD} control rail 207a of the gate control circuitry 206. In this manner, when the gate control circuitry 206 applies voltage to the gate 213 via the gate contact 219, current flows between the source and drain terminals 211 from the always-on 202 V_{DD} rail to the power-gated 104 V_{DD} rail. The configuration of the V_{SS} transistor 208b is similar except the connections are to the V_{SS} rails rather than the V_{DD} rails.

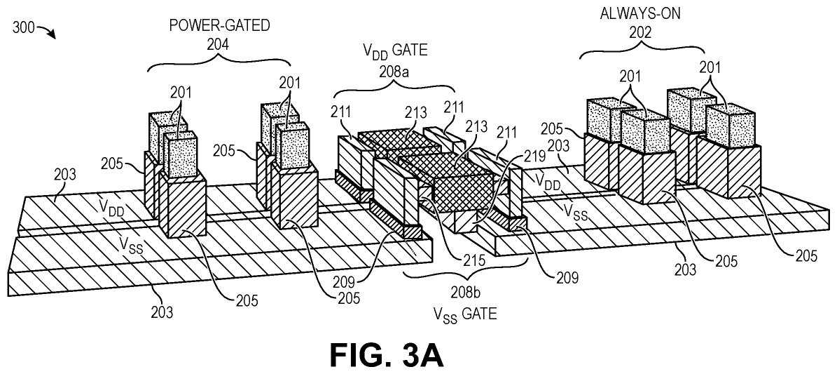

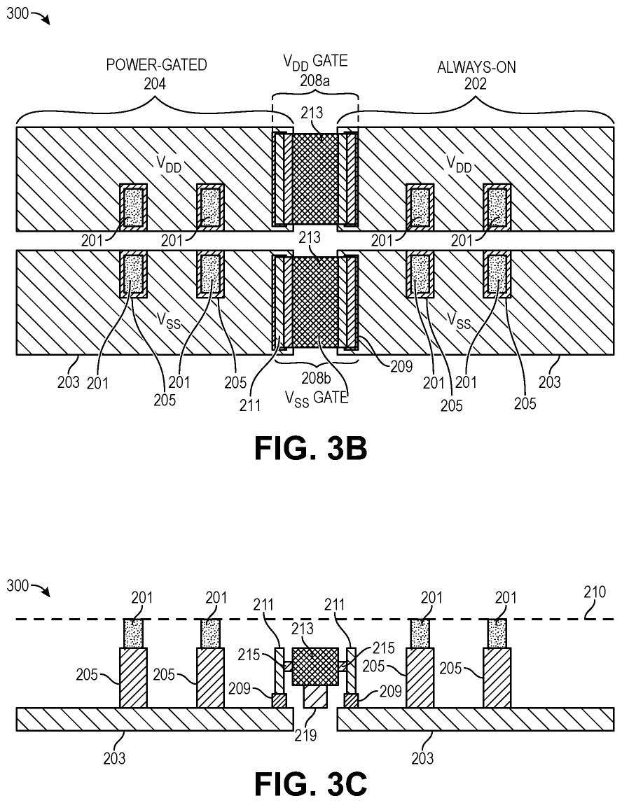

FIGS. 3A-C illustrate an example embodiment of vertical backside power gates 300 for a single circuit row. In the illustrated embodiment, the vertical power gates 300 are similar to the horizontal power gates 200 of FIGS. 2A-C, except the transistors 208a-b are oriented vertically with a much narrower width. Further, the channel 215 is visible from the perspectives shown for the vertical power gates 300.

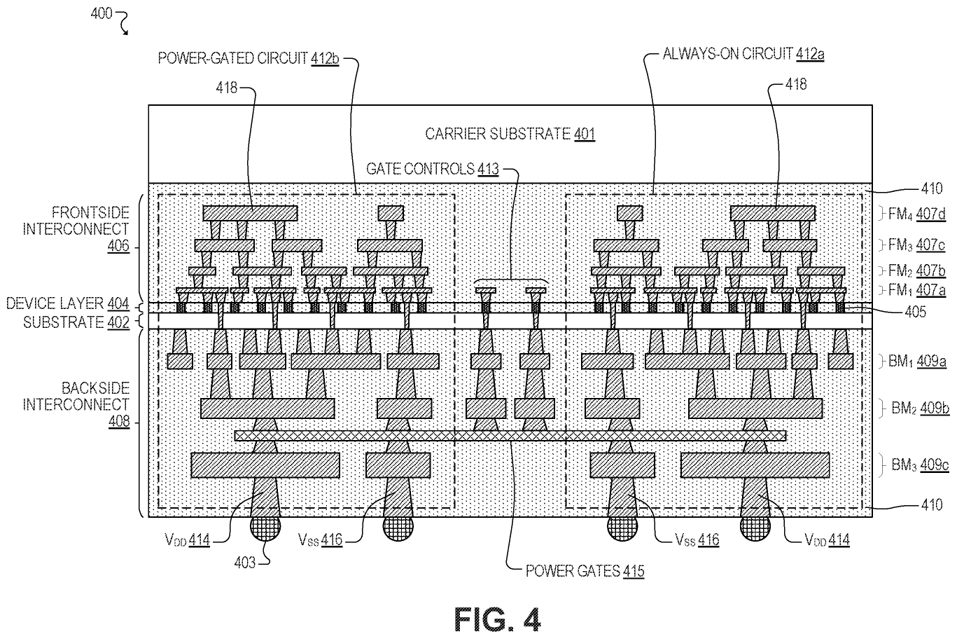

FIG. 4 illustrates a cross-section of an example integrated circuit (IC) die 400 with backside power gating. In the illustrated embodiment, for example, IC 400 includes multiple circuits or circuit blocks 412a-b, including an always-on circuit 412a and a power-gated circuit 412b, along with backside power gates 415 to switch or control the supply of power between the always-on circuit 412a and the power-gated circuit 412b, as described further below.

In the illustrated embodiment, IC 400 includes a silicon substrate 402, a device layer 404 above the substrate 402, frontside and backside interconnects 406, 408 above and below the device layer 404 and the substrate 402, respectively (e.g., for signaling and power delivery), and backside power gates or switches 415 below the substrate 402. IC 400 also includes a carrier substrate 401 attached above the frontside interconnect 406 for structural support, conductive (e.g., metal) bumps 403 on the bottom surface to electrically couple IC 400 with another electronic device (e.g., another IC die/chip, an IC package, circuit board, etc.), and one or more inter-layer dielectrics (ILDs) 410 to fill the remaining areas.

The device layer 404 includes one or more semiconductor devices 405 such as transistors (e.g., to implement logic circuitry for the respective circuit blocks 412a-b, gate controls 413, etc.). The frontside interconnect 406 includes multiple frontside metal (FM) layers (FM₁₋₄) 407a-d (e.g., primarily for signaling), and the backside interconnect 408 includes multiple backside metal (BM) layers (BM₁₋₃) 409a-c (e.g., primarily for power supply and ground connections).

The device layer 404 and interconnects 406, 408 collectively implement logic circuitry 405 and power supply (V_{DD}) 414, ground (V_{SS}) 416, and signal 418 networks for multiple circuits or circuit blocks, including an always-on circuit 412a and a power-gated circuit 412b.

Further, the backside power gates 415 switch or control the supply of power between the always-on circuit 412a and the power-gated circuit 412b, thus selectively powering the power-gated circuit 412b using the power supply (V_{DD}) 414 and ground (V_{SS}) 416 connections from the always-on circuit 412a. In some embodiments, the power gates 415 may be implemented using the embodiments shown in FIGS. 2 and 3.

For example, the power gates 415 may include one or more backside transistors to switch one or both of the power supply (V_{DD}) 414 and/or ground (V_{SS}) 416 nets. In particular, a single backside transistor may be used to switch either the power supply (V_{DD}) net 414 or the ground (V_{SS}) net 416. In the illustrated embodiment, the power gate transistors 415 are between the second and third backside metal layers (BM₂, BM₃) 409b-c in the backside interconnect 408 and are electrically coupled to the power supply (V_{DD}) 414 and ground (V_{SS}) 416 nets.

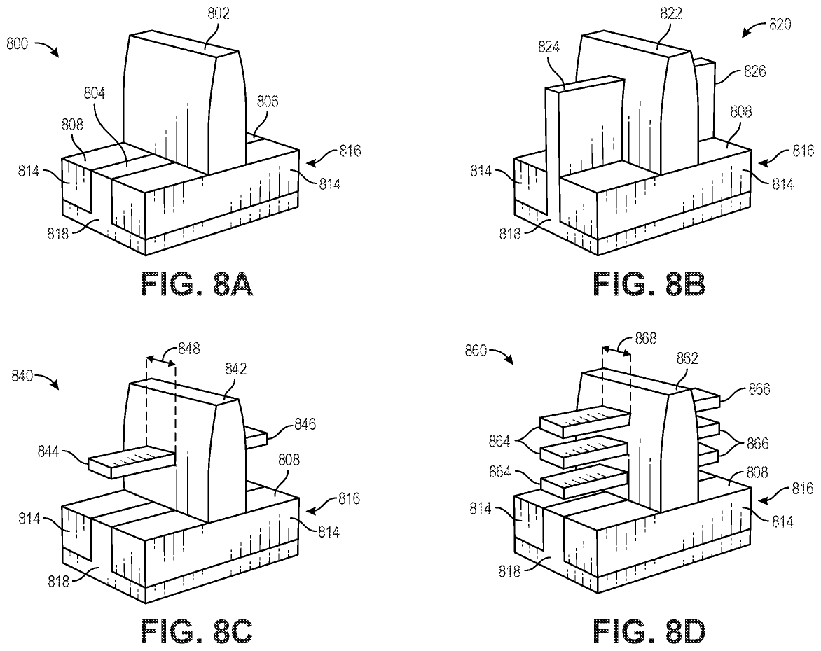

In some embodiments, some or all of the backside transistors used in the power gates 415 may be thin-film transistors (TFT) (e.g., transistors made of thin semiconductor films or thin-film semiconductor materials), such as two-dimensional (2D) transistors, oxide thin-film transistors (TFTs), etc. 2D transistors may refer to transistors that are made of, or include, one or more 2D semiconductor films/materials (e.g., in the transistor channel), such as transition-metal dichalcogenide monolayers (TMDs), graphene, etc. TMDs may refer to atomically thin semiconductors of the type MX₂, where M is a transition-metal atom (e.g., molybdenum (Mo), tungsten (W)) and X is a chalcogen atom (e.g., sulfur(S), selenium (Se), tellurium (Te)). Graphene may refer to a monolayer of carbon (C) atoms. Oxide thin-film transistors may refer to thin film transistors where the semiconductor is a metal oxide compound (e.g., in the transistor channel), such as indium tin oxide (ITO), indium tungsten oxide (IWO), indium gallium zinc oxide (IGZO), etc. Thus, in some embodiments, the TFT power gates 415 may be made of one or more materials that include elements such as oxygen (O), indium (In), gallium (Ga), molybdenum (Mo), tin (Sn), tungsten (W), zinc (Zn), sulfur(S), selenium (Se), tellurium (Te), and/or carbon (C), including, without limitation, TMD monolayers, graphene, indium tin oxide (ITO), indium tungsten oxide (IWO), and indium gallium zinc oxide (IGZO). In some embodiments, the backside transistors may be similar to transistors 800, 820, 840, 860 of FIGS. 8A-D, except formed with thin-film materials such as those described above (e.g., 2D semiconductor films, metal oxide films).

Alternatively, in other embodiments, the backside transistors used in the power gates 415 may be made of, or include, any other materials that are compatible with the back-end-of-line (BEOL) processing (e.g., thermal budget).

In the illustrated embodiment, the backside power gates 415 are controlled by frontside gate controls 413. The gate controls 413 include devices/transistors 405 in device layer 404, which are electrically coupled to the power gates 415 through traces/vias in the backside interconnect 408.

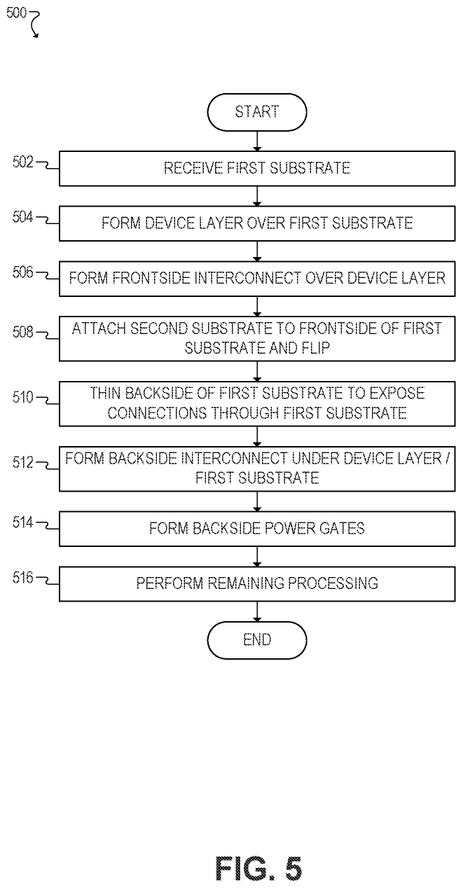

An example process flow for forming IC 400 is described below in connection with FIG. 5.

FIG. 5 illustrates a flowchart 500 for forming an integrated circuit (IC) with backside power gates in accordance with certain embodiments. It will be appreciated in light of the present disclosure that the illustrated process flow is only one example methodology for arriving at the example ICs shown and described throughout this disclosure (e.g., ICs 100, 200, 300, 400).

The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The illustrated process flow may be used to form one or more IC dies that respectively include a silicon substrate, a device layer over the substrate, frontside and backside interconnects over and under the device layer and the substrate, respectively (e.g., for signaling and power delivery), and backside power gates under the substrate. In some embodiments, the device layer and interconnects may collectively implement logic circuitry with signal, power, and ground nets for one or more circuits or circuit blocks on the respective IC dies, such as one or more always-on circuits and one or more power-gated circuits. Further, power to the always-on circuits may be unswitched (e.g., the always-on circuits always receive power when the IC receives power), while power to the power-gated circuits may be switched by the backside power gates (e.g., the power-gated circuits selectively receive power based on the one or more power switches). In some embodiments, the power gates may be part of a voltage regulator on the respective IC dies.

The flowchart begins at block 502 by receiving a first substrate. In some embodiments, the first substrate may be a wafer or panel and may include silicon (Si). Further, the first substrate may be pre-patterned with one or more through-silicon vias (TSVs), or alternatively, the first substrate may be received without any pre-patterned TSVs and one or more TSVs may be subsequently formed in the substrate.

The flowchart then proceeds to block 504 to form a device layer over the first substrate. The device layer may include one or more devices, such as transistors (e.g., CMOS, PMOS, NMOS), to implement the logic of the respective circuits or circuit blocks along with the controls to the power gates. Moreover, one or more vias may be formed through the device layer to form electrical connections to the TSVs in the first substrate.

The flowchart then proceeds to block 506 to form a first interconnect over the device layer (e.g., on the frontside of the first substrate), which may be referred to as the frontside interconnect. For example, multiple conductive (e.g., metal) layers may be formed over the device layer, along with intervening dielectric layers separating the conductive layers. The conductive layers, which may also be referred to as metal layers, may be made of one or more electrically-conductive materials that include one or more metals (e.g., any of the metals/alloys described throughout this disclosure). Further, the dielectric layers may include one or more dielectric materials (e.g., any of the dielectric materials described throughout this disclosure).

Moreover, conductive traces may be patterned (e.g., etched) in the frontside metal layers, and vias may be formed between the metal layers (e.g., through the intervening dielectric layers) to electrically couple traces in different metal layers. The conductive traces and vias patterned in and between the frontside metal layers may collectively form one or more signal, power, and/or ground nets for the respective circuits or circuit blocks (e.g., networks of conductive traces for providing signaling, power, and ground connections).

The signal nets (e.g., VIN, VOUT) may include one or more conductive traces used for signaling (e.g., electrical connections between inputs and outputs of devices/transistors in the device layer), which may also be referred to as signal traces or signal routing.

The power nets (e.g., V_{DD}, V_{CC}) may include one or more conductive traces for supplying power (e.g., electrical connections between the device layer and one or more power supply terminals), which may also be referred to as power supply traces, power traces, or power routing. Further, the power nets in the frontside interconnect may be connected to one or more corresponding power nets formed in the backside interconnect (e.g., as described below with respect to block 512).

The ground nets (e.g., V_{SS}) may include one or more conductive traces for providing ground connections (e.g., electrical connections between the device layer and one or more ground/reference terminals), which may also be referred to as ground traces or ground routing. Further, the ground nets in the frontside interconnect may be connected to one or more corresponding ground nets formed in the backside interconnect (e.g., as described below with respect to block 512).

The flowchart then proceeds to block 508 to attach or bond a second substrate to the frontside of the first substrate (e.g., over the frontside interconnect) and then flip the first substrate over. The second substrate may be referred to as a carrier substrate (e.g., a silicon carrier wafer or panel).

The flowchart then proceeds to block 510 to thin (e.g., grind) the backside of the first substrate to expose the connections (e.g., TSVs) formed in the first substrate.

The flowchart then proceeds to block 512 to form a second interconnect under the device layer and the first substrate (e.g., on the backside of the first substrate), which may be referred to as the backside interconnect.

For example, multiple conductive (e.g., metal) layers may be formed under the device layer and first substrate, along with intervening dielectric layers separating the conductive layers. The conductive layers, which may also be referred to as metal layers, may be made of one or more electrically-conductive materials that include one or more metals (e.g., any of the metals/alloys described throughout this disclosure). Further, the dielectric layers may include one or more dielectric materials (e.g., any of the dielectric materials described throughout this disclosure).

Moreover, conductive traces may be patterned (e.g., etched) in the backside metal layers, and vias may be formed between the metal layers (e.g., through the intervening dielectric layers) to electrically couple traces in different metal layers. The conductive traces and vias patterned in and between the backside metal layers may collectively form one or more backside power, ground, and/or signal nets for the respective circuits or circuit blocks (e.g., networks of conductive traces for providing power, ground, and signaling connections). For example, the backside power and ground nets may electrically couple the corresponding frontside power and ground nets to one or more backside power supply terminals and ground terminals, respectively (e.g., through the vias in the first substrate and device layer), and the backside signal nets may electrically couple the corresponding frontside signal nets to one or more signaling terminals for off-die signaling.

In this manner, the backside interconnect is electrically coupled to the frontside interconnect (e.g., through the vias in the first substrate and device layer) to provide power supply, ground, and/or signaling connections. Moreover, the backside interconnect is also electrically coupled to power supply, ground, and/or signaling terminals, which may be provided through conductive bumps formed on the backside surface of the IC die. Further, in some embodiments, backside power gates (and associated traces/vias) may also be formed during formation of the backside interconnect, as described below with respect to block 514.

The flowchart then proceeds to block 514 to form backside power gates (also referred to as power switches) for the power-gated circuitry. The power gates may switch or control the supply of power to one or more power-gated circuits or circuit blocks (e.g., and to the devices/transistors within the power-gated circuits or circuit blocks). In various embodiments, for example, the power gates may switch power supply (V_{DD}) traces, ground (V_{SS}) traces, or both, for the power-gated circuits. Moreover, the power gates may be electrically coupled to corresponding power supply (V_{DD}) and ground (V_{SS}) traces for the always-on circuitry, thus selectively enabling power supply (V_{DD}) and ground (V_{SS}) connections from the always-on circuitry to the power-gated circuitry.

In some embodiments, the power gates may be formed under the device layer and the first substrate (e.g., on the backside of the first substrate) and may be electrically coupled to the backside interconnect. For example, in some embodiments, the power gates may be formed over, under, or within the metal layers and traces in the backside interconnect. Accordingly, the power gates may be formed during the backside interconnect processing.

In some embodiments, each power gate or switch may include one or more backside transistors to switch/control power supply (V_{DD}) and/or ground (V_{SS}) traces. For example, each backside transistor may switch either a power supply (V_{DD}) trace or a ground (V_{SS}) trace. Further, in some embodiments, some or all of the backside transistors used in the power gates may be thin-film transistors (TFT), such as two-dimensional (2D) transistors or oxide thin-film transistors (TFTs) (e.g., TFTs made of metal oxide films). In some embodiments, the thin-film transistors may be grown using thin-film deposition techniques (e.g., at low temperatures) and/or transferred from another wafer.

Further, one or more traces/vias may be formed in and between the metal layers of the backside interconnect to electrically couple the power gates (e.g., backside transistors) to corresponding gate controls (e.g., frontside transistors) in the device layer.

The flowchart then proceeds to block 516 to perform any remaining processing, such as inter-layer dielectric (ILD) filling, planarization, interconnect bump formation, etc. In wafer or panel process flows, the completed wafer or panel may be diced to singulate the IC dies on the wafer or panel. The singulated IC dies may then be incorporated into an IC package, circuit board, electronic device, system, etc.

At this point, the flowchart may be complete. In some embodiments, however, the flowchart may restart and/or certain blocks may be repeated. For example, in some embodiments, the flowchart may restart at block 502 to continue forming one or more ICs with the same or similar design.

### Example Embodiments

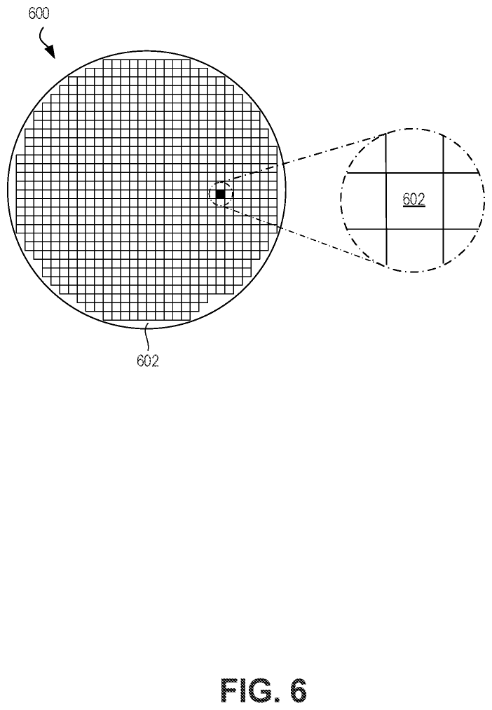

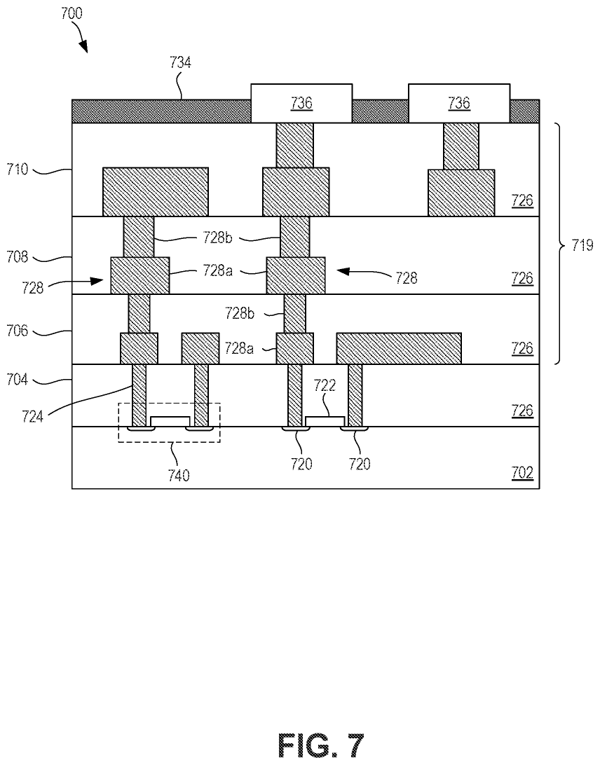

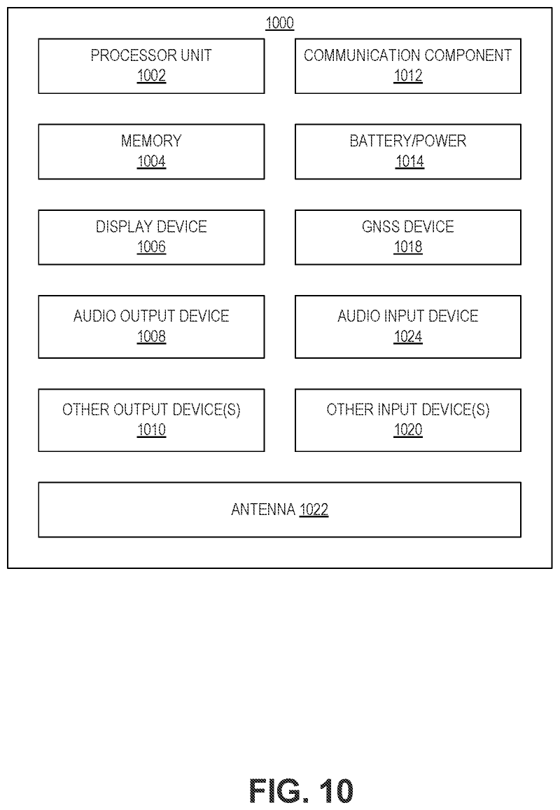

FIG. 6 is a top view of a wafer 600 and dies 602 that may be included in, or may include, any of the embodiments disclosed herein. In some embodiments, for example, the wafer 600 may include dies 602 formed with backside power gates (e.g., IC dies 100, 200, 300, 400). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies disclosed herein. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 1002 of FIG. 10) or other logic that is configured to store information in the memory devices or execute instructions stored in the memory array. Various ones of the microelectronic assemblies disclosed herein may be manufactured using a die-to-wafer assembly technique in which some dies are attached to a wafer 600 that include others of the dies, and the wafer 600 is subsequently singulated.

FIG. 7 is a cross-sectional side view of an integrated circuit device 700 that may be included in any of the embodiments disclosed herein (e.g., in any of the dies, such as IC dies 100, 200, 300, 400). One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

FIGS. 8A-D are simplified perspective views of example planar, FinFET, gate-all-around, and stacked gate-all-around transistors. In some embodiments, these transistors may be included in integrated circuits (ICs) with backside power gates (e.g., IC dies 100, 200, 300, 400). The transistors illustrated in FIGS. 8A-8D are formed on a substrate 816 having a surface 808. Isolation regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 828. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor 840 comprising a gate 842 that controls current flow between a source region 844 and a drain region 846. The transistor 840 is non-planar in that the source region 844 and the drain region 846 are elevated from the substrate surface 828.

FIG. 8D is a perspective view of a GAA transistor 860 comprising a gate 862 that controls current flow between multiple elevated source regions 864 and multiple elevated drain regions 866. The transistor 860 is a stacked GAA transistor as the gate controls the flow of current between multiple elevated S/D regions stacked on top of each other. The transistors 840 and 860 are considered gate-all-around transistors as the gates encompass all sides of the semiconductor portions that extends from the source regions to the drain regions. The transistors 840 and 860 can alternatively be referred to as nanowire, nanosheet, or nanoribbon transistors depending on the width (e.g., widths 848 and 868 of transistors 840 and 860, respectively) of the semiconductor portions extending through the gate.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components. The conductive contacts 736 may serve as any of the conductive contacts described throughout this disclosure.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736. These additional conductive contacts may serve as any of the conductive contacts described throughout this disclosure.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. These additional conductive contacts may serve as any of the conductive contacts described throughout this disclosure. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

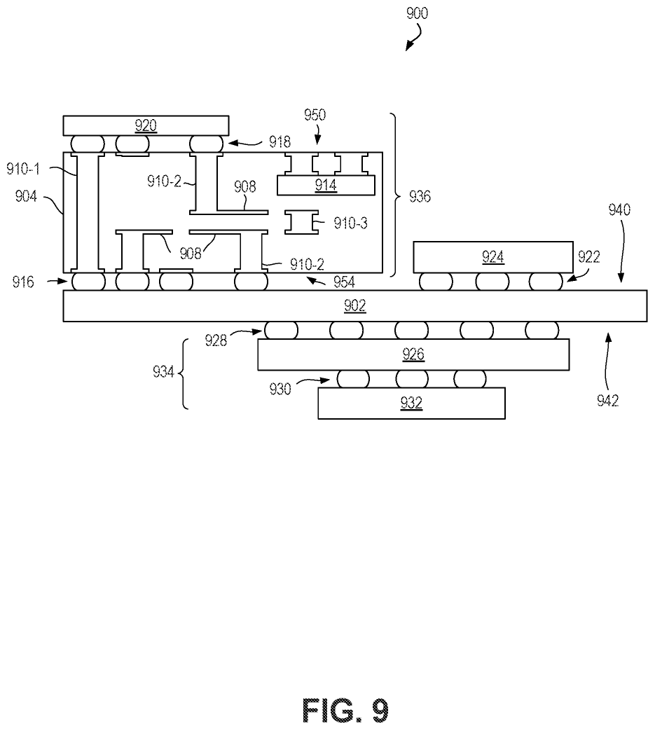

FIG. 9 is a cross-sectional side view of an integrated circuit device assembly 900 that may include any of the embodiments disclosed herein (e.g., one or more integrated circuits with backside power gates, such as ICs 100, 200, 300, 400). In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable ones of the components of the electrical device 1000 may include one or more of the integrated circuits with backside power gates (e.g., ICs 100, 200, 300, 400), integrated circuit device assemblies 900, integrated circuit components 920, integrated circuit devices 700, or integrated circuit dies 602 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16—2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include other output device(s) 1010 (or corresponding interface circuitry, as discussed above). Examples of the other output device(s) 1010 may include an audio codec, a video codec, a printer, a wired or wireless transmitter for providing information to other devices, or an additional storage device.

The electrical device 1000 may include other input device(s) 1020 (or corresponding interface circuitry, as discussed above). Examples of the other input device(s) 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.
Example 1 includes an integrated circuit die, comprising: a device layer, wherein the device layer comprises one or more transistors; a first interconnect over the device layer; a second interconnect under the device layer; and one or more power gates under the device layer, wherein the one or more power gates control power to one or more of the transistors.
Example 2 includes the integrated circuit die of Example 1, wherein: the one or more transistors are one or more first transistors; and the one or more power gates comprise one or more second transistors.
Example 3 includes the integrated circuit die of Example 2, wherein the one or more second transistors comprise one or more thin-film semiconductor materials.
Example 4 includes the integrated circuit die of Example 3, wherein the one or more thin-film semiconductor materials comprise one or more two-dimensional (2D) semiconductor materials.
Example 5 includes the integrated circuit die of Example 4, wherein the one or more 2D semiconductor materials comprise one or more transition-metal dichalcogenide monolayers.
Example 6 includes the integrated circuit die of any of Examples 1-5, wherein: the first interconnect is electrically coupled to one or more of the transistors; the second interconnect is electrically coupled to the first interconnect; and the one or more power gates are electrically coupled to the second interconnect.
Example 7 includes the integrated circuit die of Example 6, wherein: the first interconnect comprises one or more signal traces electrically coupled to one or more of the transistors; and the second interconnect comprises one or more power supply traces and one or more ground traces, wherein the one or more power supply traces are electrically coupled to one or more power supply terminals, and wherein the one or more ground traces are electrically coupled to one or more ground terminals.
Example 8 includes the integrated circuit die of Example 7, wherein the one or more power gates comprise: one or more first power gates to switch one or more of the power supply traces; and one or more second power gates to switch one or more of the ground traces.
Example 9 includes the integrated circuit die of any of Examples 1-8, wherein: the one or more transistors comprise a plurality of transistors; and the integrated circuit die further comprises a plurality of circuits, wherein individual circuits comprise one or more of the plurality of transistors, and wherein power to at least some of the circuits is switched by the one or more power gates.
Example 10 includes the integrated circuit die of any of Examples 1-9, further comprising: a substrate between the device layer and the second interconnect, wherein the substrate comprises silicon; and one or more vias through the substrate and the device layer, wherein the first and second interconnects are electrically coupled through the one or more vias.
Example 11 includes the integrated circuit die of any of Examples 1-10, further comprising a carrier substrate over the first interconnect.
Example 12 includes the integrated circuit die of any of Examples 1-11, wherein: the first interconnect is on a frontside of the integrated circuit die; and the second interconnect and the one or more power gates are on a backside of the integrated circuit die.
Example 13 includes an electronic device, comprising: a substrate comprising silicon; a device layer over the substrate, wherein the device layer comprises a plurality of transistors; a plurality of circuits, wherein individual circuits comprise one or more of the transistors; and one or more power switches under the substrate, wherein the one or more power switches switch power to one or more of the circuits.
Example 14 includes the electronic device of Example 13, wherein: the plurality of transistors are a plurality of first transistors; and the one or more power switches comprise one or more second transistors, wherein the one or more second transistors comprise one or more two-dimensional semiconductor materials.
Example 15 includes the electronic device of any of Examples 13-14, wherein the plurality of circuits comprises: one or more first circuits, wherein the one or more first circuits always receive power when the electronic device receives power; and one or more second circuits, wherein the one or more second circuits selectively receive power based on the one or more power switches.
Example 16 includes the electronic device of any of Examples 13-15, further comprising: a first interconnect over the device layer, wherein the first interconnect comprises a plurality of signal traces, wherein the signal traces are electrically coupled to one or more of the transistors; and a second interconnect under the substrate, wherein the second interconnect comprises a plurality of power supply traces and a plurality of ground traces, wherein the power supply traces are electrically coupled to one or more power supply terminals, and wherein the ground traces are electrically coupled to one or more ground terminals; wherein individual circuits further comprise one or more of the signal traces, one or more of the power supply traces, and one or more of the ground traces.
Example 17 includes the electronic device of any of Examples 13-16, further comprising a voltage regulator, wherein the voltage regulator comprises the one or more power switches.
Example 18 includes a method, comprising: receiving a substrate, wherein the substrate comprises silicon; forming a device layer over the substrate, wherein the device layer comprises one or more transistors; forming a first interconnect over the device layer; forming a second interconnect under the substrate; and forming one or more power gates under the substrate.
Example 19 includes the method of Example 18, wherein: the one or more transistors are one or more first transistors; and the one or more power gates comprise one or more second transistors, wherein the one or more second transistors comprise one or more two-dimensional semiconductor materials.
Example 20 includes the method of any of Examples 18-19, wherein the substrate is a first substrate, and wherein the method further comprises: attaching a second substrate over the first interconnect; and thinning the first substrate before forming the second interconnect and the one or more power gates.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform comprising dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. An integrated circuit die, comprising:
a device layer, wherein the device layer comprises one or more transistors;
a first interconnect over the device layer;
a second interconnect under the device layer; and
one or more power gates under the device layer, wherein the one or more power gates control power to one or more of the transistors.

2. The integrated circuit die of claim 1, wherein:
the one or more transistors are one or more first transistors; and
the one or more power gates comprise one or more second transistors.

3. The integrated circuit die of claim 2, wherein the one or more second transistors comprise one or more thin-film semiconductor materials.

4. The integrated circuit die of claim 3, wherein the one or more thin-film semiconductor materials comprise one or more two-dimensional (2D) semiconductor materials.

5. The integrated circuit die of claim 4, wherein the one or more 2D semiconductor materials comprise one or more transition-metal dichalcogenide monolayers.

6. The integrated circuit die of claim 1, wherein:
the first interconnect is electrically coupled to one or more of the transistors;
the second interconnect is electrically coupled to the first interconnect; and
the one or more power gates are electrically coupled to the second interconnect.

7. The integrated circuit die of claim 6, wherein:
the first interconnect comprises one or more signal traces electrically coupled to one or more of the transistors; and
the second interconnect comprises one or more power supply traces and one or more ground traces, wherein the one or more power supply traces are electrically coupled to one or more power supply terminals, and wherein the one or more ground traces are electrically coupled to one or more ground terminals.

8. The integrated circuit die of claim 7, wherein the one or more power gates comprise:
one or more first power gates to switch one or more of the power supply traces; and
one or more second power gates to switch one or more of the ground traces.

9. The integrated circuit die of claim 1, wherein:
the one or more transistors comprise a plurality of transistors; and
the integrated circuit die further comprises a plurality of circuits, wherein individual circuits comprise one or more of the plurality of transistors, and wherein power to at least some of the circuits is switched by the one or more power gates.

10. The integrated circuit die of claim 1, further comprising:
a substrate between the device layer and the second interconnect, wherein the substrate comprises silicon; and
one or more vias through the substrate and the device layer, wherein the first and second interconnects are electrically coupled through the one or more vias.

11. The integrated circuit die of claim 1, further comprising a carrier substrate over the first interconnect.

12. The integrated circuit die of claim 1, wherein:
the first interconnect is on a frontside of the integrated circuit die; and
the second interconnect and the one or more power gates are on a backside of the integrated circuit die.

13. An electronic device, comprising:
a substrate comprising silicon;
a device layer over the substrate, wherein the device layer comprises a plurality of transistors;
a plurality of circuits, wherein individual circuits comprise one or more of the transistors; and
one or more power switches under the substrate, wherein the one or more power switches switch power to one or more of the circuits.

14. The electronic device of claim 13, wherein:
the plurality of transistors are a plurality of first transistors; and
the one or more power switches comprise one or more second transistors, wherein the one or more second transistors comprise one or more two-dimensional semiconductor materials.

15. The electronic device of claim 13, wherein the plurality of circuits comprises:
one or more first circuits, wherein the one or more first circuits always receive power when the electronic device receives power; and
one or more second circuits, wherein the one or more second circuits selectively receive power based on the one or more power switches.

16. The electronic device of claim 13, further comprising:
a first interconnect over the device layer, wherein the first interconnect comprises a plurality of signal traces, wherein the signal traces are electrically coupled to one or more of the transistors; and
a second interconnect under the substrate, wherein the second interconnect comprises a plurality of power supply traces and a plurality of ground traces, wherein the power supply traces are electrically coupled to one or more power supply terminals, and wherein the ground traces are electrically coupled to one or more ground terminals;
wherein individual circuits further comprise one or more of the signal traces, one or more of the power supply traces, and one or more of the ground traces.

17. The electronic device of claim 13, further comprising a voltage regulator, wherein the voltage regulator comprises the one or more power switches.

18. A method, comprising:
receiving a substrate, wherein the substrate comprises silicon;
forming a device layer over the substrate, wherein the device layer comprises one or more transistors;
forming a first interconnect over the device layer;
forming a second interconnect under the substrate; and
forming one or more power gates under the substrate.

19. The method of claim 18, wherein:
the one or more transistors are one or more first transistors; and
the one or more power gates comprise one or more second transistors, wherein the one or more second transistors comprise one or more two-dimensional semiconductor materials.

20. The method of claim 18, wherein the substrate is a first substrate, and wherein the method further comprises:
attaching a second substrate over the first interconnect; and
thinning the first substrate before forming the second interconnect and the one or more power gates.
